(19) United States
(12) Patent Application Publication
(10) Pub. No.: US 2023/0352365 A1
(43) Pub. Date: Nov. 2, 2023

(54) THERMOCONDUCTIVE MATERIAL AND ELECTRONIC COMPONENT

(71) Applicant: Panasonic Intellectual Property Management Co., Ltd., Osaka (JP)

(72) Inventors: Youji SHIRATO, Hokkaido (JP); Norihiro KAWAMURA, Hokkaido (JP); Masaya HATTORI, Tokyo (JP)

(21) Appl. No.: 18/043,857

(22) PCT Filed: Sep. 10, 2021
(86) PCT No.: PCT/JP2021/033407

§ 371 Date: Mar. 2, 2023

(30) Foreign Application Priority Data
Sep. 14, 2020 (JP) 2020-153416

(51) Int. Cl. H01L 23/42; H01L 23/40; H01L 21/48; H01L 23/373

(52) U.S. Cl. CPC H01L 23/42; H01L 23/4006; H01L 21/4882; H01L 23/3735; H01L 2023/4087; H01L 2023/405

(57) ABSTRACT

A thermoconductive material includes a carbonaceous substance as a main component and has a plurality of screw insertion portions into which a plurality of screws are to be inserted on a one-to-one basis in a thickness direction defined with respect to the thermoconductive material. The thermoconductive material includes an inside region located at a side of a central portion of the thermoconductive material with respect to the plurality of screw insertion portions and an outside region located at a side of an outer edge portion of the thermoconductive material with respect to the inside region. The outside region includes a support portion which is at least part of the outside region. When a pressure of 500 kPa is applied in the thickness direction, an outside thickness which is a thickness of the support portion is greater than an inside thickness which is a greatest thickness of the inside region.

### TECHNICAL FIELD

The present disclosure relates to thermoconductive materials and electronic components, and specifically, to a thermoconductive material which is to be disposed between a heat generator and a heat dissipator and an electronic component.

### BACKGROUND ART

In recent years, increased number of electric vehicles, hybrid vehicles, and the like have adopted motors as main drive sources and auxiliary drive sources for traveling. An inverter configured to control such vehicles adopts an Insulated Gate Bipolar Transistor (IGBT). The IGBT is attached to a heat dissipator with screws and the like to release generated heat.

Regarding such a technique, Patent Literature 1 discloses a heat dissipation component-equipped power module including: a power module including a base plate, a ceramic insulation substrate bonded to the base plate, and a semiconductor element bonded to the ceramic insulation substrate; and a heat dissipation component attached to a heat dissipation sheet on the base plate, wherein a flatness of a surface on an opposite side of the base plate from the ceramic insulation substrate is greater than or equal to 20 μm.

Besides this method, there is a method of providing grease or the like between the IGBT and the heat dissipator to smoothly transfer heat from the IGBT to the heat dissipator. However, when the grease is used, thermal conductivity is insufficient, and in addition, expansion of the IGBT due to repeated heat generation and cooling of the IGBT gradually pushes out the grease, which may deteriorate the thermal conductivity. Another available method is to provide, for heat transfer, a solid heat conductive sheet such as a graphite sheet between the IGBT and the heat dissipator. However, when the solid heat conductive sheet is fastened with the screws, force is applied more to peripheral portions than to a central portion of the solid heat conductive sheet. Therefore, the solid heat conductive sheet cannot be bought into satisfactorily close contact with a central portion of a heat generator where the heat generator generates a large amount of heat. Thus, this method provides no satisfactory cooling effect.

### CITATION LIST

### Patent Literature

Patent Literature 1: JP 2019-067801 A

### SUMMARY OF INVENTION

An object of the present disclosure is to provide: a thermoconductive material which is brought into satisfactorily close contact even with a central portion of a heat generator where the heat generator generates a large amount of heat, which has improved cooling performance, and which has excellent reliability; and an electronic component.

A thermoconductive material according to an aspect of the present disclosure is a thermoconductive material which is to be disposed between a heat generator and a heat dissipator and which is to be fastened together with the heat generator and the heat dissipator with a plurality of screws. The thermoconductive material includes a carbonaceous substance as a main component. The thermoconductive material has a plurality of screw insertion portions into which the plurality of screws are to be inserted on a one-to-one basis in a thickness direction defined with respect to the thermoconductive material. The thermoconductive material includes an inside region and an outside region. The inside region is a region located at a side of a central portion of the thermoconductive material with respect to the plurality of screw insertion portions. The outside region is a region located at a side of an outer edge portion of the thermoconductive material with respect to the inside region. The outside region includes a support portion which is at least part of the outside region. When a pressure of 500 kPa is applied in the thickness direction, an outside thickness which is a thickness of the support portion is greater than an inside thickness which is a greatest thickness of the inside region.

An electronic component according to an aspect of the present disclosure is an electronic component including a heat generator, a heat dissipator, a thermoconductive material between the heat generator and the heat dissipator, and a plurality of screws which fasten the heat generator, the thermoconductive material, and the heat dissipator together. The plurality of screws are inserted in the thermoconductive material in a thickness direction defined with respect to the thermoconductive material. The thermoconductive material includes a carbonaceous substance as a main component. The thermoconductive material includes an inside region and an outside region. The inside region is a region located at a side of a central portion of the thermoconductive material with respect to central axes of the plurality of screws. The outside region is a region located at a side of an outer edge portion of the thermoconductive material with respect to the inside region. The outside region includes a support portion which is at least part of the outside region. When a pressure of 500 kPa is applied in the thickness direction, an outside thickness which is a thickness of the support portion is greater than an inside thickness which is a greatest thickness of the inside region.

### BRIEF DESCRIPTION OF DRAWINGS

FIG. 1 is a schematic top view of an example of a thermoconductive material according to the present embodiment;

FIG. 2 is a schematic sectional view of the thermoconductive material of FIG. 1;

FIG. 3 is a schematic sectional view of an example of an electronic component according to the present embodiment;

FIGS. 4A to 4D are schematic top views of other examples of the thermoconductive material according to the present embodiment;

FIGS. 5A and 5B are schematic top views of other examples of the thermoconductive material according to the present embodiment;

FIGS. 6A to 6D are schematic sectional views of other examples of the thermoconductive material according to the present embodiment; and

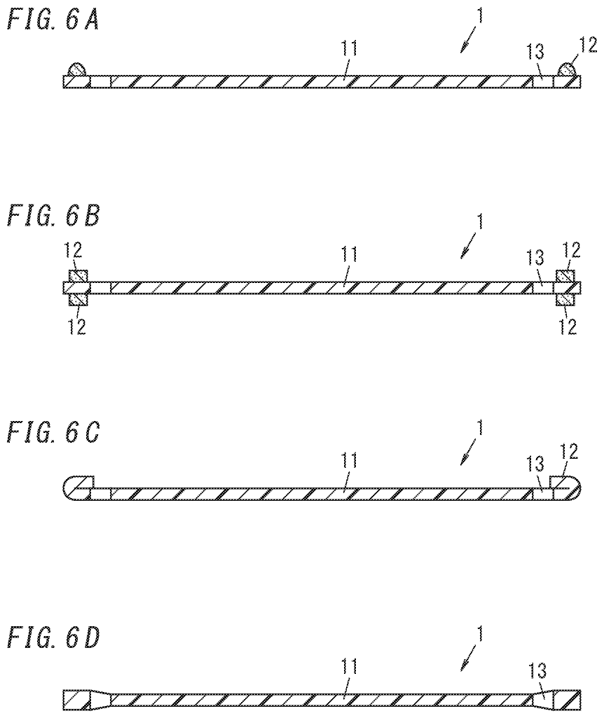

FIGS. 7A to 7C are schematic perspective views of thermoconductive materials used in Examples.

### DESCRIPTION OF EMBODIMENTS

### 1. Overview

A thermoconductive material and an electronic component according to an embodiment of the present disclosure will be described. Note that the embodiment described below is merely one of various embodiments of the present disclosure. The embodiment described below may be variously modified according to the design as long as the object of the present disclosure is achieved.

The thermoconductive material (Thermal Interface Material (TIM)) is a material which is to be disposed between two members to mediate transfer of heat between the two members.

The thermoconductive material 1 according to the present embodiment is a thermoconductive material to be disposed between a heat generator and a heat dissipator and is to be fastened together with the heat generator and the heat dissipator with a plurality of screws. The thermoconductive material 1 includes a carbonaceous substance as a main component and has a plurality of screw insertion portions into which the plurality of screws are to be inserted on a one-to-one basis in a thickness direction defined with respect to the thermoconductive material. The thermoconductive material 1 includes an inside region and an outside region. The inside region is a region located at the side of a central portion of the thermoconductive material 1 with respect to the plurality of screw insertion portions. The outside region is a region located at the side of an outer edge portion of the thermoconductive material 1 with respect to the inside region. The outside region includes a support portion which is at least part of the outside region. When a pressure of 500 kPa is applied in the thickness direction, an outside thickness which is a thickness of the support portion is greater than an inside thickness which is the greatest thickness of the inside region.

A conventional thermoconductive material is, for example, a rectangular graphite sheet having screw holes or the like at its corners. Into the screw holes or the like, screws are inserted and fasten a heat generator and a heat dissipator together, thereby bringing the thermoconductive material into close contact with the heat generator and the heat dissipator while compressing the thermoconductive material. In such a thermoconductive material, a larger force is usually applied to a peripheral portion of the thermoconductive material. Therefore, the peripheral portion is more compressed, deteriorating adhesion at a central portion of the thermoconductive material. This increases thermal resistance, so that a satisfactory cooling effect is difficultly obtained.

In contrast, the thermoconductive material 1 of the present embodiment is configured such that the outside thickness is greater than the inside thickness when a pressure of 500 kPa is applied in the thickness direction. The outside thickness is the thickness of the support portion which is at least part of the outside region, which is the region located at the side of the outer edge portion with respect to the inside region. The inside thickness is the greatest thickness of the inside region, which is the region located at the side of the central portion with respect to the screw insertion portions. In this configuration, the support portion of the outside region serves as a support. Therefore, when fastened with the screws, the thermoconductive material can be brought into sufficiently close contact even with a central portion of the heat generator where the heat generator generates a large amount of heat. This enables the heat resistance in the inside region to be reduced, thereby improving the cooling performance. As a result, the reliability of the thermoconductive material and the electronic component including the thermoconductive material can be improved.

An electronic component 100 according to the present embodiment is an electronic component including a heat generator, a heat dissipator, a thermoconductive material 1 between the heat generator and the heat dissipator, and a plurality of screws which fasten the heat generator, the thermoconductive material 1, and the heat dissipator together. The plurality of screws are inserted in the thermoconductive material 1 in a thickness direction defined with respect to the thermoconductive material 1. The thermoconductive material 1 includes a carbonaceous substance as a main component. The thermoconductive material 1 includes an inside region and an outside region. The inside region is a region located at the side of a central portion of the thermoconductive material 1 with respect to central axes of the plurality of screws. The outside region is a region located at the side of an outer edge portion of the thermoconductive material 1 with respect to the inside region. The outside region includes a support portion which is at least part of the outside region. When a pressure of 500 kPa is applied in the thickness direction, an outside thickness which is a thickness of the support portion is greater than an inside thickness which is the greatest thickness of the inside region.

According to the electronic component 100 of the present embodiment, the thermoconductive material 1 is configured such that the outside thickness is greater than the inside thickness. The outside thickness is a thickness of the support portion which is at least part of the outside region, which is the region located at the side of the outer edge portion with respect to the inside region. The inside thickness is the greatest thickness of the inside region, which is the region located at the side of the central portion with respect to the central axes of the screws. In this configuration, the support portion of the outside region serves as a support. Therefore, when fastened with the screws, the thermoconductive material can be brought into sufficiently close contact even with a central portion of the heat generator where the heat generator generates a large amount of heat. This enables the heat resistance in the inside region to be reduced, thereby improving the cooling performance As a result, the reliability of the electronic component 100 can be improved.

### 2. Details

<Thermoconductive Material>

The thermoconductive material 1 according to the present embodiment includes a carbonaceous substance as a main component. The “carbonaceous substance” means a substance mainly composed of carbon, that is, composed of only carbon except that atoms or molecules as impurities which may inevitably mixed into the substance may be included. Here, “includes a carbonaceous substance as a main component” means that the percentage of the carbonaceous substance in substances constituting the thermoconductive material 1 is, for example, greater than or equal to 50% by mass, preferably greater than or equal to 70% by mass, and more preferably greater than or equal to 90% by mass.

Examples of the carbonaceous substance include carbonaceous sheets such as graphite and graphene, carbonaceous particles such as carbon black, Ketjen black, and acetylene black, and carbonaceous fibers such as carbon nanotubes, carbon nanohorns, and vapor-grown carbon fibers.

The thermoconductive material 1 has the plurality of screw insertion portions. The screw insertion portions are portions into which respective screws are to be inserted in the thickness direction defined with respect to the thermoconductive material 1. Each screw insertion portion preferably has a hole shape or a cutout shape. In this case, the screws can be fixed more firmly, and thereby, the adhesion can be further improved, the cooling performance can be further improved, and the reliability can be further improved.

The thermoconductive material 1 preferably has four or more screw insertion portions. Further, four of the four or more screw insertion portions are preferably arranged at the vertices of a quadrangle. In this case, the thermoconductive material 1 can be fixed more firmly, and thereby, the adhesion can be further improved, the cooling performance can be further improved, and the reliability can be further improved. The four screw insertion portions are more preferably arranged at the vertices of a rectangle or a square.

The thermoconductive material 1 includes the inside region (hereinafter also referred to as an inside region A) and the outside region (hereinafter also referred to as an outside region A).

The inside region A is a region located at the side of the central portion of the thermoconductive material 1 with respect to the plurality of screw insertion portions. More specifically, the inside region A is a region located at the side of the central portion of the thermoconductive material 1 with respect to parts, closest to the central portion of the thermoconductive material 1, of the screw insertion portions. In the case where two screw insertion portions are provided, the inside region A is a region located at the side of the central portion of the thermoconductive material 1 with respect to parts, closest to the central portion of the thermoconductive material 1, of the two screw insertion portions. In the case where four or more screw insertion portions are provided, and four of the four or more screw insertion portions are arranged at the vertices of a quadrangle, the inside region A is a quadrangular region whose vertices are parts, closest to the central portion of the thermoconductive material 1, of the four screw insertion portions. In this case, the adhesion can be further improved, the cooling performance can be further improved, and the reliability can be further improved.

The outside region A is a region located at the side of the outer edge portion of the thermoconductive material 1 with respect to the inside region A. That is, the outside region A is a region outside the inside region A. The outside region A includes the support portion (hereinafter also referred to as a support portion A) which is at least part of the outside region A.

In the thermoconductive material 1, the outside thickness (hereinafter also referred to as an outside thickness A) is greater than the inside thickness (hereinafter also referred to as an inside thickness A). The inside thickness A is the greatest thickness of the inside region A when a pressure of 500 kPa is applied in the thickness direction. The outside thickness A is the thickness of the support portion A when a pressure of 500 kPa is applied in the thickness direction. The thermoconductive material 1 is configured such that the outside thickness A is greater than the inside thickness A, and thereby, the support portion A of the outside region A serves as a support. Therefore, when fastened with the screws, the thermoconductive material can be brought into sufficiently close contact even with the central portion of the heat generator where the heat generator generates a large amount of heat. This enables the heat resistance in the inside region A to be reduced, thereby improving the cooling performance. As a result, the reliability of the thermoconductive material 1 and the electronic component 100 including the thermoconductive material 1 can be improved.

The shape of the thermoconductive material 1 is not particularly limited but is, for example, a sheet shape, and is a rectangular shape in plan view.

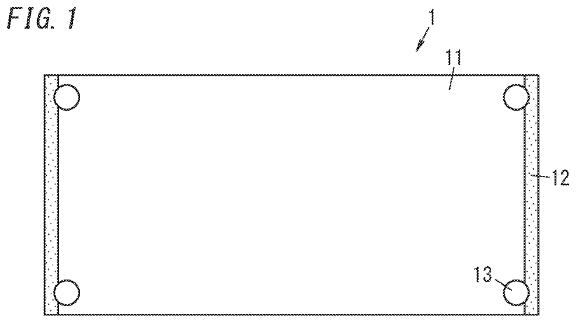

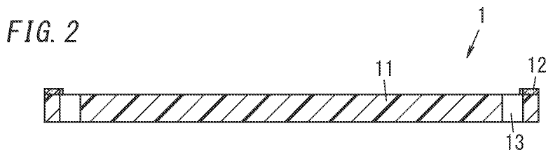

FIG. 1 is a top view of an example of the thermoconductive material 1 of the present embodiment. FIG. 2 is a sectional view of the thermoconductive material 1 of FIG. 1. The thermoconductive material 1 shown in FIGS. 1 and 2 includes a carbonaceous sheet 11, the screw insertion portions 13, and an overlap 12 overlapping the outside region A of the carbonaceous sheet 11. In the thermoconductive material 1 of FIGS. 1 and 2, the overlap 12 is arranged on the outside region A to form laminate structures on the outside region A such that the outside thickness A is greater than the inside thickness A. In this case, the adhesion can be further improved, the cooling performance can be further improved, and the reliability can be further improved.

The dimension of the thermoconductive material 1 is appropriately selectable in accordance with the size of an IGBT on which the thermoconductive material 1 is to be mounted. For example, the thermoconductive material 1 may be in the shape of a rectangle of a about 60 mm×120 mm and may have a thickness of about 0.2 mm at its central portion. Overlaps 12 may be formed, for example, by affixing polyethylene terephthalate (PET) tapes, each having a thickness of about 10 μm, onto both short sides of the carbonaceous sheet 11 which is in the shape of a rectangle. The thermoconductive material 1 has a thickness of, for example, about 0.125 mm when a pressure of 500 kPa is applied to the inside region A and a thickness of, for example, about 0.135 mm when a pressure of 500 kPa is applied to the outside region A.

The carbonaceous sheet 11 is a sheet containing a carbonaceous substance. Examples of the carbonaceous sheet 11 include a graphite sheet and a graphene sheet. The carbonaceous sheet 11 may be, for example, a sheet obtained by impregnating a sheet such as a graphite sheet with a resin, or a sheet formed by molding a mixture of a carbonaceous substance, a resin, and the like.

The overlap 12 is a portion overlapping the outside region A of the carbonaceous sheet 11. On the outside region A, a laminate structure is formed by the overlap 12 and the carbonaceous sheet 11.

The shape of the overlap 12 is not particularly limited but is, for example, a sheet shape, a projection shape, or the like. The material for the overlap 12 is not particularly limited but may be the same as a material for the carbonaceous sheet 11, or may be a resin, metal, or the like. Examples of the resin include PET. PET is hardly compressed at a pressure of about 500 kPa and is therefore preferably used as a material for the overlap 12. The overlap 12 may include a single layer or a single member or may include two or more layers or members.

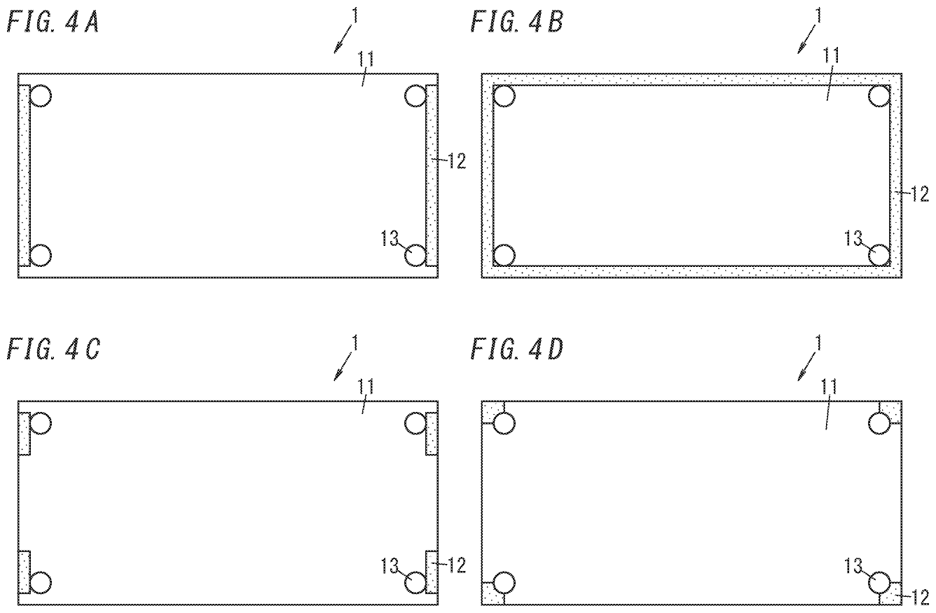

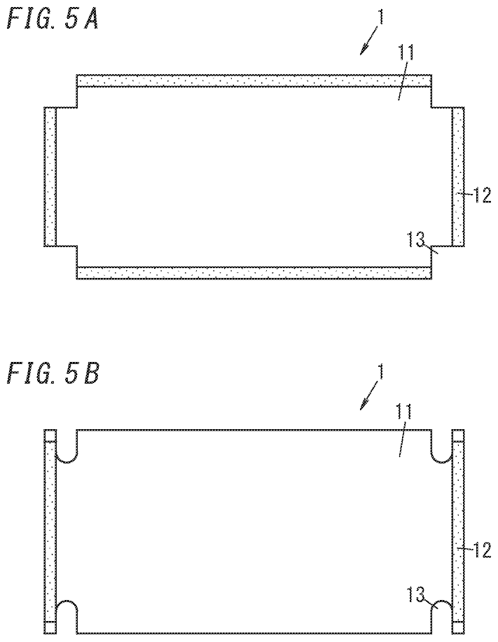

When each screw insertion portion 13 has a hole shape, the overlap 12 on the outside region A is formed over the entire length of each of both short sides of the rectangular shape in the case of the thermoconductive material 1 of FIG. 1. Such a location of the overlap 12 is preferable because the thermoconductive material 1 readily warps in the length direction when the thermoconductive material 1 has a rectangular shape. The location of the overlap 12 on the outside region A is not limited to this example but may include, for example, part of each of both short sides of the rectangular shape (FIG. 4A), a whole part of both long sides and short sides of the rectangular shape (FIG. 4B), separated parts on each of both short sides of the rectangular shape (FIG. 4C), and four corners of the rectangular shape (FIG. 4D). When each screw insertion portion 13 has a cutout shape, the location of the overlap 12 on the outside region A is not particularly limited, but may include, for example, a whole part of both long sides and short sides of the rectangle except for the screw insertion portions 13 (FIG. 5A), and part of each of both short sides of the rectangle (FIG. 5B).

Examples of the laminate structure formed by the carbonaceous sheet 11 and the overlap 12 may include laminate structures formed by the carbonaceous sheet 11 and overlaps 12 each having a projection shape (see 6A of the drawings) or laminate structures formed by overlaps 12 each having a sheet shape and provided on both surfaces of the carbonaceous sheet 11 (see 6B).

Alternatively, the laminate structure may be formed by folding back at least part of the outside region A (see 6C). In this case, the thermoconductive material 1 can be formed more easily.

As shown in 6D, the thermoconductive material 1 may be formed by shaving the inside region A such that the inside thickness A is smaller than the outside thickness A.

The difference between the outside thickness A and the inside thickness A, that is, a value obtained by subtracting the inside thickness A from the outside thickness A is preferably greater than or equal to 10 μm. In this case, even the central portion of the thermoconductive material 1 can be stably brought into contact with the heat generator, thereby further lowering the temperature of the heat generator. This difference is realizable, for example, by setting the thickness of the overlap 12 forming the laminate structure to be greater than or equal to 10 μm. The difference is more preferably greater than or equal to 20 μm, and much more preferably greater than or equal to 30 μm. The upper limit of the difference is not particularly limited but is, for example, greater than or equal to 1500 μm.

The ratio of the outside thickness A to the inside thickness A (the outside thickness A/the inside thickness A) is preferably greater than or equal to 1.05. In this case, even the central portion of the thermoconductive material 1 can be stably brought into contact with the heat generator, thereby further lowering the temperature of the heat generator. This ratio is more preferably greater than or equal to 1.1, and much more preferably greater than or equal to 1.2. The upper limit of the ratio is not particularly limited but is, for example, less than or equal to 10.

The compression ratio is preferably higher than or equal to 30% when a pressure of 500 kPa is applied to at least part of the inside region A in the thickness direction. As described above, the thermoconductive material 1 is configured to have a high compression ratio, and therefore, even when a surface of the heat generator or the heat dissipator has recesses and projections, the thermoconductive material 1 can be deformed in accordance with the recesses and projections, thereby reducing the thermal resistance. The compression ratio is more preferably greater than or equal to 40%, and much more preferably greater than or equal to 50%. The upper limit of the compression ratio is not particularly limited but is, for example, less than or equal to 90%. Note that the compression ratio is the percentage of a decrement in the thickness of the thermoconductive material 1 when a pressure of 500 kPa is applied in the thickness direction of the thermoconductive material 1 with respect to the thickness (initial thickness) of the of the thermoconductive material 1 without the application of the pressure. The compression ratio can be measured by a method according to ASTM D5470 and is calculated by the equation: (1−T2/T1)×100(%), where T1 is the initial thickness of the thermoconductive material 1, and T2 is the thickness of the thermoconductive material 1 when a compressive pressure of 500 kPa is applied.

When each screw insertion portion 13 has a hole shape, the thermoconductive material 1 has four or more screw insertion portions 13, and four of the four or more screw insertion portions 13 are arranged at the vertices of a quadrangle, the outside region A preferably has the support portion A in a region outside a quadrangle whose vertices are centers of the four screw insertion portions 13. The support portion A is arranged in the region of the outside region A, thereby further reinforcing a support by the support portion A, and when the thermoconductive material 1 is fastened with a screw, the adhesion can be further improved, the cooling performance can be further improved, and the reliability can be further improved. In addition, the support portion A is preferably disposed in a region of the outside region A, wherein the region is located at the side of the outer edge portion of the thermoconductive material 1 with respect to the central axes of the plurality of screws.

The thermoconductive material 1 described above includes the laminate structure formed on the outside region A. However, the thermoconductive material 1 of the present embodiment is not limited to this example. For example, the thermoconductive material 1 is at least configured such that the outside thickness A is greater than the inside thickness A, and different materials may be used for the outside region A and the inside region A. For Example, the thermoconductive material 1 may include a carbonaceous sheet 11 having a density higher in the outside region A than in the inside region A or may include a carbonaceous sheet 11 whose outside region A is impregnated with a resin or the like to lower the compression ratio.

<Electronic Component>

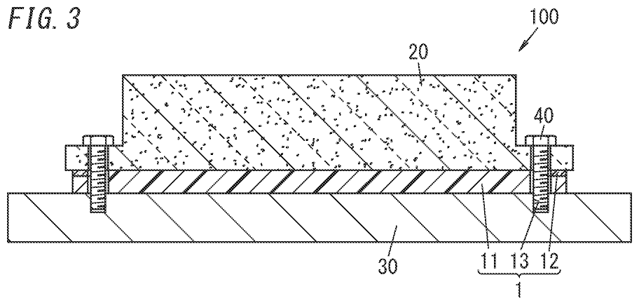

FIG. 3 is a sectional view of an example of the electronic component 100 according to an embodiment of the present disclosure. The electronic component 100 of FIG. 3 includes the thermoconductive material 1, a heat generator 20, a heat dissipator 30, and screws 40.

The heat generator 20 is a member that generates heat. The heat generator 20 is, for example, a semiconductor component. Examples of the semiconductor component include, but are not limited to, a transistor, a center processing unit (CPU), a microprocessing unit (MPU), a driver IC, and memory. The heat generator 20 may include, for example, a heat spreader and a chip portion fixed on the heat spreader. The heat spreader is a plate-shaped member made of metal or the like. The chip portion is, for example, a semiconductor package. In this case, the chip portion may be disposed on a portion except for an outer edge portion of the heat spreader, and a plurality of screw holes or the like penetrating the heat spreader may be formed in the outer edge portion.

The heat dissipator 30 is a member to which heat generated by the heat generator 20 is to be transferred. Heat can be released from the heat dissipator 30. The heat dissipator 30 is, for example, a heat sink. The heat dissipator 30 shown in FIG. 3 is a plate-shaped heat sink, and the heat dissipator 30 may further include a heat radiating fin. The heat dissipator 30 has a plurality of screw holes and the like formed at locations corresponding to the plurality of screw holes and the like in the heat generator 20.

A thermoconductive material 1 shown in FIG. 3 includes a carbonaceous sheet 11, an overlap 12, and screw insertion portions 13. The thermoconductive material 1 in an electronic component 100 has the same configuration as the thermoconductive material 1 described above except for an inside region and an outside region.

The thermoconductive material 1 includes an inside region (hereinafter also referred to as an inside region B) and an outside region (hereinafter also referred to as an outside region B).

The inside region B is a region located at the side of a central portion of the thermoconductive material 1 with respect to central axes of the plurality of screws 40. More specifically, in the case where two screws 40 are provided, the inside region B is a region located at the side of the central portion of the thermoconductive material 1 with respect to the central axes of the two screws 40. In the case where four or more screws 40 are provided, and four of the four or more screws are arranged at vertices of a quadrangle, the inside region B is a quadrangular region whose vertices are central axes of the four screws. In this case, the adhesion can be further improved, the cooling performance can be further improved, and the reliability of the electronic component 100 can be further improved.

The outside region B is a region located at the side of an outer edge portion of the thermoconductive material 1 with respect to the inside region B. That is, the outside region B is a region outside the inside region B. The outside region B includes a support portion (hereinafter also referred to as a support portion B) which is at least part of the outside region B.

In the thermoconductive material 1 of the electronic component 100, an outside thickness (hereinafter also referred to as an outside thickness B) is greater than an inside thickness (hereinafter also referred to as an inside thickness B). The inside thickness B is the greatest thickness of the inside region B when a pressure of 500 kPa is applied in a thickness direction defined with respect to the thermoconductive material 1. The outside thickness B is the thickness of the support portion B when a pressure of 500 kPa is applied in the thickness direction. In the electronic component 100, the thermoconductive material 1 is configured such that the outside thickness B is greater than the inside thickness B. In this configuration, the support portion B of the outside region B serves as a support. Therefore, when fastened with the screws, the thermoconductive material can be brought into sufficiently close contact even with a central portion of a heat generator where the heat generator generates a large amount of heat. This enables the heat resistance in the inside region B to be reduced, thereby improving the cooling performance As a result, the reliability of the electronic component 100 can be improved.

### Example

The present disclosure will be described in more detail below with reference to examples, but the present disclosure is not limited to the examples described below.

The relationship between the number of sheets stacked on each other and the width or location of an overlapping section of the thermoconductive material is evaluated.

1. The Number of Stacked Sheets

[Comparative Example 1 and Examples 1 to 3]

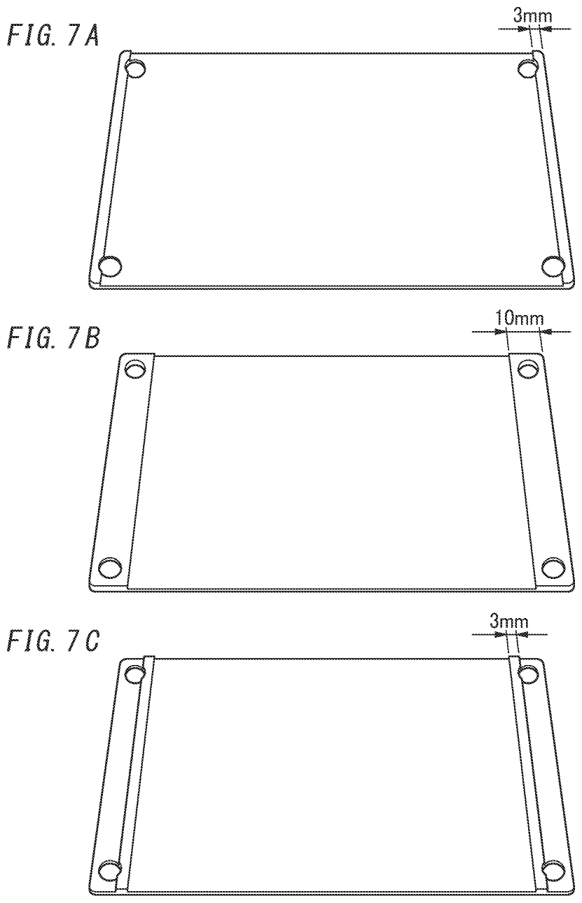

Thermoconductive materials were prepared by forming overlaps each having a width of 3 mm by stacking a graphite sheet (thickness: 0.2 mm) on each of both ends of a base TIM (graphite sheet, thickness: 0.2 mm), wherein the width of the overlapping section was 3 mm as shown in FIG. 7A and the number of sheets stacked on each other (the number of stacked sheets of each overlap in the overlapping section) was varied such that the number of sheets is zero (in Comparative Example 1), three (in Example 1), five (in Example 2), and seven (in Example 3), and then, the junction temperature (Tj (° C.) of each of the thermoconductive materials was measured by using a commercially available semiconductor module. ΔTj (° C.) is the difference between Tj and a heat dissipator temperature (25° C.). (Measuring condition) I_{C}: 220 A, V_{GE}: 15 V, ON/OFF: 180 second/180 seconds, Heat dissipator temperature=25° C., Tightening torque: 4 N·m

In the thermoconductive material of FIG. 7A, for example, the inside region is a rectangular region whose vertices are parts, closest to the central portion of the thermoconductive material, of the four screw insertion portions each having a hole shape (hereinafter also referred to as screw holes), and the outside region is a region outside the inside region. In the thermoconductive material of FIG. 7A, the inside thickness (the greatest thickness of the inside region) is, for example, the thickness of the central portion of the thermoconductive material when a pressure of 500 kPa is applied in the thickness direction, and the outside thickness (the thickness of the support portion which is at least part of the outside region) is, for example, the thickness of the overlapping section of the thermoconductive material.

The number of sheets stacked on each other, the inside thickness (mm), the outside thickness (mm), ΔTj (° C.), and Tj (° C.) in each of Comparative Example 1 and Examples 1 to 3 are shown in Table 1 below.

TABLE 1

| | | Inside | Outside | | |
|---|---|---|---|---|---|
| | The number of | thickness | thickness | ΔTj | Tj |
| | stacked sheets | (mm) | (mm) | (° C.) | (° C.) |
| Comparative | 0 | 0.16 | 0.16 | 89.3 | 114.3 |
| Example 1 | | | | | |
| Example 1 | 3 | 0.16 | 0.64 | 85.0 | 110.0 |
| Example 2 | 5 | 0.16 | 0.96 | 84.5 | 109.5 |
| Example 3 | 7 | 0.16 | 1.28 | 84.8 | 109.8 |

From results shown in Table 1, it can be seen that the thermoconductive materials of the examples in each of which the outside thickness is greater than the inside thickness have improved cooling performance compared to the thermoconductive material of the comparative example in which the outside thickness is not greater than the inside thickness (the outside thickness is the same as the inside thickness).

2. Location or Width of Overlapping Section

Regarding the location of the overlapping section or the width of the overlapping section, thermoconductive materials were prepared which include overlaps, each made of a graphite sheet (thickness: 0.2 mm), at both ends of the base TIM (graphite sheet, thickness: 0.2 mm), where the number of sheets stacked on each other was three. The junction temperature (Tj (° C.) was measured in the same manner as described above.

### Example 1

As shown in FIG. 7A, the thermoconductive material in this example has overlapping sections each having a width of 3 mm and being formed in a region outside the screw holes (partially overlapping the screw holes) (the same as that in Example 1 described above).

### Comparative Example 2

As shown in FIG. 7B, the thermoconductive material in this comparative example has overlapping sections each having a width of 10 mm and being formed to extend from a region on an inner side with respect to screw holes to an outer side with respect to the screw holes.

### Comparative Example 3

As shown in FIG. 7C, the thermoconductive material in this comparative example has overlapping sections each having a width of 3 mm and being formed in regions on an inner side with respect to screw holes (partially overlapping the screw holes).

When a pressure of 500 kPa is applied in the thickness direction defined with respect to the thermoconductive material, the inside thickness and the outside thickness are as defined below. In Example 1, the inside thickness is, for example, the thickness at the central portion of the thermoconductive material of FIG. 7A, and the outside thickness is, for example, the thickness of the overlapping sections of the thermoconductive material. In Comparative Example 2, the inside thickness is, for example, the thickness of a portion which is part of the overlapping sections of the thermoconductive material of FIG. 7B and which is located at the side of the central portion of the thermoconductive material with respect to the screw holes. The outside thickness is, for example, the thickness of a portion which is part of the overlapping sections and which is located at the side of an outer edge portion of the thermoconductive material with respect to the screw holes. In Comparative Example 3, the inside thickness is, for example, the thickness of a portion which is part of the overlapping sections of the thermoconductive material of FIG. 7C and which is on the inner side with respect to the screw holes (between the two screw holes). The outside thickness is, for example, the thickness of a portion which is part of the overlapping sections and which is on the outer side with respect to the screw holes.

The position and width (mm) of the overlapping section, the inside thickness (mm), the outside thickness (mm), ΔTj (° C.), and Tj (° C.) in each of Example 1, Comparative Examples 2, and Comparative Example 3 are shown in Table 2 below.

TABLE 2

| | | | | Inside | Outside | | |
|---|---|---|---|---|---|---|---|
| | | Overlapping section | | thickness | thickness | ΔTj | Tj |
| | FIG. | Location | Width | (mm) | (mm) | (° C.) | (° C.) |
| Example 1 | FIG. 7A | Outer side | 3 mm | 0.16 | 0.64 | 85.0 | 110.0 |
| | | with respect | | | | | |
| | | to screw hole | | | | | |
| Comparative | FIG. 7B | Outer side | 10 mm | 0.64 | 0.64 | 93.1 | 118.1 |
| Example 2 | | and inner | | | | | |
| | | side with | | | | | |
| | | respect to | | | | | |
| | | screw hole | | | | | |
| Comparative | FIG. 7C | Inner side | 3 mm | 0.64 | 0.64 | 113.3 | 138.3 |
| Example 3 | | with respect | | | | | |
| | | to screw hole | | | | | |

From results shown in Table 2, it can be seen that the thermoconductive material of the example in which the outside thickness is greater than the inside thickness has excellent cooling performance On the other hand, the thermoconductive materials of comparative examples in which the outside thickness is not greater than the inside thickness (the outside thickness is the same as the inside thickness) has poor cooling performance.

As can be seen from the embodiments and examples described above, a thermoconductive material (1) according to a first aspect of the present disclosure is a thermoconductive material to be provided between a heat generator (20) and a heat dissipator (30) and to be fastened together with the heat generator (20) and the heat dissipator (30) with a plurality of screws. The thermoconductive material (1) includes a carbonaceous substance as a main component. The thermoconductive material (1) has a plurality of screw insertion portions (13) into which the plurality of screws are to be inserted on a one-to-one basis in a thickness direction defined with respect to the thermoconductive material (1). The thermoconductive material (1) includes an inside region and an outside region. The inside region is a region located at a side of a central portion of the thermoconductive material (1) with respect to the plurality of screw insertion portions (13). The outside region is a region located at a side of an outer edge portion of the thermoconductive material (1) with respect to the inside region. The outside region includes a support portion which is at least part of the outside region. When a pressure of 500 kPa is applied in the thickness direction, an outside thickness which is a thickness of the support portion is greater than an inside thickness which is the greatest thickness of the inside region.

According to the first aspect, the support portion of the outside region serves as a support. Therefore, when fastened with the screws, the thermoconductive material (1) can be brought into satisfactorily close contact even with a central portion of the heat generator (20) where the heat generator (20) generates a large amount of heat. This enables the heat resistance in the inside region to be reduced, thereby improving the cooling performance. As a result, the reliability of the thermoconductive material (1) and the electronic component (100) including the thermoconductive material (1) can be improved.

In a second aspect, referring to the first aspect, of the present disclosure, the plurality of screw insertion portions (13) each have a hole shape or a cutout shape.

According to the second aspect, screws (40) can be more firmly fixed. This enables the adhesion to be further improved, the cooling performance to be further improved, and the reliability to be further improved.

In a third aspect, referring to the first or second aspect, of the present disclosure, the plurality of screw insertion portions (13) include four or more screw insertion portions (13), and four of the four or more screw insertion portions (13) are arranged at vertices of a quadrangle.

According to the third aspect, the thermoconductive material (1) can be fixed more strongly. This enables the adhesion to be further improved, the cooling performance to be further improved, and the reliability to be further improved.

In a fourth aspect, referring to the third aspect, of the present disclosure, the inside region is a quadrangular region whose vertices are parts, closest to the central portion of the thermoconductive material (1), of the four screw insertion portions (13).

The fourth aspect enables the adhesion to be further improved, the cooling performance to be further improved, and the reliability to be further improved.

In a fifth aspect, referring to the third or fourth aspect, of the present disclosure, the plurality of screw insertion portions (13) each have a hole shape, and the support portion is in a region of the outside region, the region being outside a quadrangle whose vertices are centers of the four screw insertion portions (13).

According to the fifth aspect, the support portion is disposed in the region of the outside region to further reinforce a support by the support portion, which enables the adhesion to be further improved, the cooling performance to be further improved, and the reliability to be further improved when the thermoconductive material (1) is fastened with the screws (40).

In a sixth aspect, referring to any one of the first to fifth aspects, of the present disclosure, a difference between the outside thickness and the inside thickness is greater than or equal to 10 μm.

The sixth aspect enables even the central portion of the thermoconductive material (1) to be brought into contact with the heat generator (20), thereby further reducing the temperature of the heat generator (20).

In a seventh aspect, referring to any one of the first to sixth aspects, of the present disclosure, a compression ratio is greater than or equal to 30%. when the pressure of 500 kPa is applied to at least part of the inside region in the thickness direction.

According to the seventh aspect, the thermoconductive material (1) is configured to have a high compression ratio, and therefore, even when a surface of the heat generator (20) or the heat dissipator (30) has recesses and projections, the thermoconductive material (1) can be deformed in accordance with the recesses and projections, thereby reducing the thermal resistance.

An eighth aspect, referring to any one of the first to seventh aspects, of the present disclosure, further includes a laminate structure on the outside region.

The eighth aspect enables the adhesion to be further improved, the cooling performance to be further improved, and the reliability to be further improved.

In a ninth embodiment, referring to the eighth aspect, of the present disclosure, the laminate structure is formed by folding back at least part of the outside region.

The ninth aspect enables the thermoconductive material (1) to be more easily produced.

An electronic component (100) of a tenth aspect of the present disclosure includes a heat generator (20), a heat dissipator (30), the thermoconductive material (1) between the heat generator (20) and the heat dissipator (30), and a plurality of screws (40) which fasten the heat generator (20), the thermoconductive material (1), and the heat dissipator (30) together. The plurality of screws (40) are inserted in the thermoconductive material (1) in a thickness direction defined with respect to the thermoconductive material (1). The thermoconductive material (1) includes a carbonaceous substance as a main component. The thermoconductive material (1) includes an inside region and an outside region. The inside region is a region located at a side of a central portion of the thermoconductive material (1) with respect to central axes of the plurality of screws (40). The outside region is a region located at a side of an outer edge portion of the thermoconductive material (1) with respect to the inside region. The outside region includes a support portion which is at least part of the outside region. When a pressure of 500 kPa is applied in the thickness direction, an outside thickness which is a thickness of the support portion is greater than an inside thickness which is a greatest thickness of the inside region.

In the tenth aspect, the support portion of the outside region serves as a support. Therefore, when fastened with the screws, the thermoconductive material can be brought into sufficiently close contact even with a central portion of the heat generator (20) where the heat generator (20) generates a large amount of heat. This enables the heat resistance in the inside region to be reduced, thereby improving the cooling performance. As a result, the reliability of the electronic component (100) can be improved.

### REFERENCE SIGNS LIST

1 Thermoconductive Material
11 Carbonaceous Sheet
12 Overlap
13 Screw Insertion Portion
20 Heat Generator
30 Heat Dissipator
40 Screw
100 Electronic Components

1. A thermoconductive material to be disposed between a heat generator and a heat dissipator and to be fastened together with the heat generator and the heat dissipator with a plurality of screws, the thermoconductive material comprising a carbonaceous substance as a main component,
the thermoconductive material having a plurality of screw insertion portions into which the plurality of screws are to be inserted on a one-to-one basis in a thickness direction defined with respect to the thermoconductive material,
the thermoconductive material including an inside region and an outside region, the inside region being a region located at a side of a central portion of the thermoconductive material with respect to the plurality of screw insertion portions, the outside region being a region located at a side of an outer edge portion of the thermoconductive material with respect to the inside region,
the outside region including a support portion which is at least part of the outside region,
when a pressure of 500 kPa is applied in the thickness direction, an outside thickness which is a thickness of the support portion being greater than an inside thickness which is a greatest thickness of the inside region.

2. The thermoconductive material of claim 1, wherein
the plurality of screw insertion portions each have a hole shape or a cutout shape.

3. The thermoconductive material of claim 1, wherein
the plurality of screw insertion portions include four or more screw insertion portions, and
four of the four or more screw insertion portions are arranged at vertices of a quadrangle.

4. The thermoconductive material of claim 3, wherein
the inside region is a quadrangular region whose vertices are parts, closest to the central portion of the thermoconductive material, of the four screw insertion portions.

5. The thermoconductive material of claim 3, wherein
the plurality of screw insertion portions each have a hole shape, and
the support portion is in a region of the outside region, the region being outside a quadrangle whose vertices are centers of the four screw insertion portions.

6. The thermoconductive material of claim 1, wherein
a difference between the outside thickness and the inside thickness is greater than or equal to 10 μm.

7. The thermoconductive material of claim 1, wherein
a compression ratio is greater than or equal to 30% when the pressure of 500 kPa is applied to at least part of the inside region in the thickness direction.

8. The thermoconductive material of claim 1, further comprising a laminate structure on the outside region.

9. The thermoconductive material of claim 8, wherein
the laminate structure is formed by folding back at least part of the outside region.

10. An electronic component comprising:
a heat generator;
a heat dissipator;
a thermoconductive material between the heat generator and the heat dissipator; and
a plurality of screws which fasten the heat generator, the thermoconductive material, and the heat dissipator together,
the plurality of screws being inserted in the thermoconductive material in a thickness direction defined with respect to the thermoconductive material,
the thermoconductive material including a carbonaceous substance as a main component,
the thermoconductive material including an inside region and an outside region, the inside region being a region located at a side of a central portion of the thermoconductive material with respect to central axes of the plurality of screws, the outside region being a region located at a side of an outer edge portion of the thermoconductive material with respect to the inside region,
the outside region including a support portion which is at least part of the outside region,
when a pressure of 500 kPa is applied in the thickness direction, an outside thickness which is a thickness of the support portion being greater than an inside thickness which is a greatest thickness of the inside region.
